(19) United States
(12) Patent Application Publication
(10) Pub. No.: US 2014/0186581 A1
(43) Pub. Date: Jul. 3, 2014

(54) PRIMER-COATED COPPER FOIL HAVING SUPERIOR ADHESIVE STRENGTH AND METHOD FOR PRODUCING THE SAME

(71) Applicant: SAMSUNG ELECTRO-MECHANICS CO., LTD., Suwon-si (KR)

(72) Inventors: Seok Kyu LEE, Suwon-si (KR); Takayuki HAZE, Suwon-si (KR); Soon Jin CHO, Suwon-si (KR)

(73) Assignee: SAMSUNG ELECTRO-MECHANICS CO., LTD., Suwon-si (KR)

(21) Appl. No.: 14/140,398

(22) Filed: Dec. 24, 2013

(30) Foreign Application Priority Data
Dec. 28, 2012 (KR) 10-2012-0157129

(51) Int. Cl. H05K 1/05; H05K 3/00

(52) U.S. Cl. CPC H05K 1/056; H05K 3/0064
USPC 428/141; 156/247

(57) ABSTRACT

Disclosed herein are a primer-coated copper foil and a method for producing the same. The primer-coated copper foil includes a copper foil layer; and a primer resin layer having a first surface on which the copper foil layer is coated and a second surface as a counter side on which a roughness is formed, so that the primer-coated copper foil can exhibit excellent adhesive strength.

### CROSS REFERENCE TO RELATED APPLICATION

This application claims the benefit of Korean Patent Application No. 10-2012-0157129, filed on Dec. 28, 2012, entitled “Primer-Coated Copper Foil Having Superior Adhesive Strength and Method for Producing the Same”, which is hereby incorporated by reference in its entirety into this application.

### BACKGROUND OF THE INVENTION

1. Technical Field

The present invention relates to a primer-coated copper foil having excellent adhesive strength, a method for producing the same, and a printed circuit board using the same.

2. Description of the Related Art

With the development of electronic devices and request for complicated functions, a printed circuit board has continuously been requested to have a lower weight, a thinner thickness, and a smaller size. In order to satisfy these requests, wirings of the printed circuit board becomes more complex, more densified, and higher functioned.

As the electronic device becomes smaller sized and higher functioned, the multilayer printed circuit board has been also requested to have more density, higher functions, a smaller size, and a thinner thickness. In particular, wirings of the multilayer printed circuit board have been developed to be finer and highly densified. For this reason, thermal, mechanical, and electrical properties of the insulating layer of the multilayer printed circuit board become important. In particular, in order to minimize warpage that occurs due to the reflow during the mounting procedure of an electronic and electric device, a low coefficient of thermal expansion (CTE), a high glass transition temperature (Tg), and high modulus characteristics are requested.

Meanwhile, in several wet etching processes in which products after completing the vacuum press, having various thicknesses, are processed by a semi-additive process, by applying the primer-coated copper foil, the primer layer may be torn out at an interface between the prepreg and the primer-coated copper foil due to friction with a fine driving roll, friction between products during transfer of the product, and friction due to careless handling.

In the prior art, Patent Document 1 discloses that the primer is bonded with a prepreg by using viscosity of the primer resin itself. However, using only viscosity of this resin itself has a limit in securing strong adhesive strength between the primer and the prepreg.

Patent Document 1: Korean Patent No. 10-1061243

### SUMMARY OF THE INVENTION

Therefore, the present inventors confirmed that, when a roughness is formed on a surface of a primer of a primer-coated copper foil, excellent adhesive strength between the primer and a prepreg was exhibited, and the present invention was completed based on this fact.

The present invention has been made in an effort to provide a primer-coated copper foil exhibiting superior adhesive strength.

Further, the present invention has been made in an effort to provide a method for producing the primer-coated copper foil in a simple and economical manner.

Further, the present invention has been made in an effort to provide a printed circuit board having the primer-coated copper foil.

According to a preferred embodiment of the present invention, there is provided a primer-coated copper foil, including: a copper foil layer; and a primer resin layer having a first surface on which the copper foil layer is coated and a second surface as a counter side on which a roughness is formed.

The primer resin layer may contain at least one epoxy resin selected from a naphthalene based epoxy resin, a bisphenol A epoxy resin, a phenol novolac epoxy resin, a cresole novolac epoxy resin, a rubber modified epoxy resin, and a phosphorous-based epoxy resin.

The primer resin layer may have a thickness of 2 to 10 μm.

The roughness may have an arithmetic average roughness value (Ra) of 0.2 to 0.6.

The roughness may have a maximum arithmetic average roughness value (Rz) of 2 to 6.

According to another preferred embodiment of the present invention, there is provided a method for producing a primer-coated copper foil having a roughness formed on a surface thereof, the method including: providing a template film having one surface having a roughness formed thereon, on which a release layer is coated; laminating a primer resin layer having a first surface on which a copper foil layer is coated and a second surface as an opposite side thereof on the template film such that the second surface of the primer resin layer is laminated on the release layer of the template film; pressing the laminated template film and the primer-coated copper foil; drying and hardening the pressed template film and primer-coated copper foil; and removing the template film coated with the release layer.

The release layer may have a thickness of 1 to 3 μm.

The template film may be a polyethylene terephthalate film.

The roughness may have an arithmetic average roughness value (Ra) of 0.2 to 0.6.

The roughness may have a maximum arithmetic average roughness value (Rz) of 2 to 6.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view of a general printed circuit board to which a primer-coated copper foil according to the present invention is applicable;

FIG. 2 provides images showing weak adhesive strength between a primer-coated copper foil that is generally used and the prepreg;

FIGS. 3A and 3B are cross-sectional views comparing a cross section of the primer-coated copper foil according to the present invention (FIG. 3A) and a cross section of the copper foil of the prior art (FIG. 3B); and

FIG. 4 is a flow chart showing a method for producing the primer-coated copper foil according to the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

As an insulating substrate applied for a general printed circuit board, a copper laminate which is produced by overlapping a predetermined number of prepreg, obtained by impregnating reinforced glass fabric with a binder and then drying it, and then laminating a copper foil thereon, has been used. The prepreg is generally prepared by impregnating glass fabric with a cross-linkable resin such as epoxy or the like.

Circuits are formed on the printed circuit board by a subtractive method such that a circuit width is 25 to 30 μm. In order to realize finer circuits, a modified semi-additive process (MSAP) is applied to attain a circuit width of up to 20 μm. A thin copper foil (2 to 12 μm) is bonded to an upper portion of the prepreg (PPG), as a material applied in this tenting and modified semi-additive methods, and the roughness of the copper foil is used to realize a fine circuit.

However, as the recent mobile device becomes lighter, thinner, and smaller, more signals are transmitted and thus finer circuits are requested on the board. In order to realize a printed circuit board capable of solving warpage problems of the thin film type substrate and allowing finer circuits (circuit width: 12 μm), a new material and a new process suitable for the semi-additive process (SAP) have been applied. This new material is composed of a polymer material (primer) having high adhesive strength with electroless chemical copper, which is a core of the semi-additive method, and thinly formed with an average thickness of 2 to 5 μm on the copper foil layer. Here, this is defined as a primer-coated copper (PCC).

This primer-coated copper foil is laminated together with the prepreg at the time of the laminating process, which is one of processes for producing a multilayer board. Then, the prepreg is hardened at a high temperature and a high pressure, so that the primer layer of the primer-coated copper foil and the prepreg layer have strong adhesive strength. After that, in order to perform the semi-additive process, a laser via process for interlayer connection is conducted. Then, the copper foil bonded with the primer layer is removed through entire etching, and then electroless chemical copper plating and copper electroplating are conducted.

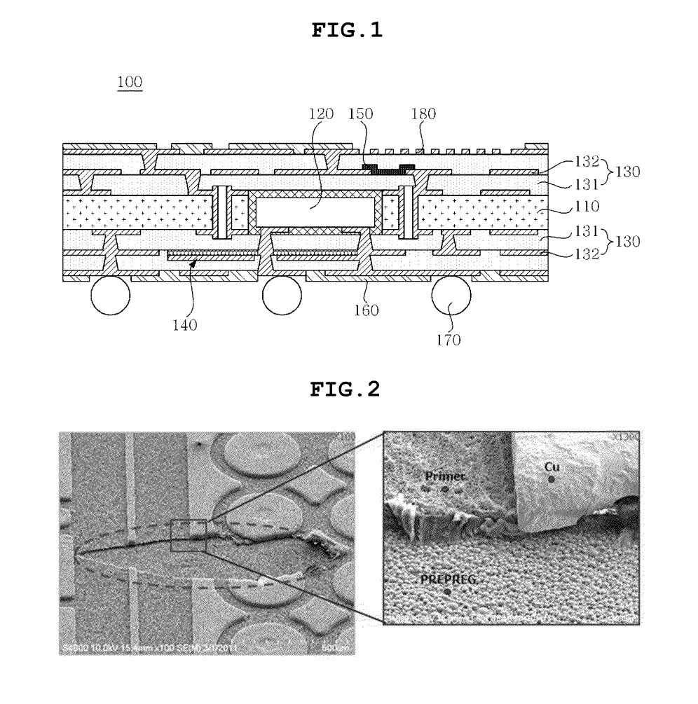

FIG. 1 is a cross-sectional view of a general printed circuit board to which a PCC according to the present invention is applicable. Referring to FIG. 1, a printed circuit board 100 may be an embedded substrate having electronic components therein. Specifically, the printed circuit board 100 may include an insulator or prepreg 110 having a cavity; an electronic component 120 disposed inside the cavity; and a buildup layer 130 disposed on at least one of an upper surface and a lower surface of the insulator or prepreg 110 including the electronic component 120. The buildup layer 130 may include an insulating layer 131 (for example, PCC) disposed on at least one of the upper surface and the lower surface of the insulator 110 and a circuit layer 132 disposed on the insulating layer 131 and implementing interlayer connection.

Here, an example of the electronic component 120 may be an active device such as a semiconductor device. In addition, the printed circuit board 100 may not have only one electronic component 120 therein but further have one or more additive electronic components, such as a capacitor 140, a resistor element 150, and the like. In a preferred embodiment of the present invention, the kind or number of electronic components is not limited. Here, the insulator or prepreg 110 and the PCC 131 may serve to give insulating property between circuit layers or between electronic components, and also serve as a structural member for maintaining rigidity of a package.

Here, when wiring density of the printed circuit board 100 is increased, the insulator or prepreg 110 and the PCC 131 require low dielectric constant characteristics in order to reduce noise between the circuit layers and parasitic capacitance, and the insulator or prepreg 110 and the PCC 131 also require low dielectric loss characteristics in order to increase the insulating property.

In the present invention, a primer-coated copper foil 131 composed on a primer resin layer having a first surface on which a copper foil layer is coated and a second surface as an opposite side, on which a roughness is formed, is used, in order to produce a primer-coated copper foil having improved adhesive strength. There are a subtractive method (tenting method), an MSAP method, an SAP method, and the like in methods for fabricating a multilayer printed circuit board. With respect to a procedure for forming circuit wirings of the multilayer printed circuit board, first, a single circuit wiring layer is formed, and in order to form another wiring layer thereon, an insulating layer for separating circuits is formed. In the case of the SAP method, there are two methods for the insulating layer 131, of using a buildup film or using a primer. The buildup film is generally used while the glass fabric is not contained therein.

Meanwhile, the primer is mainly used in the case where a thin film type multilayer board is requested. A copper foil layer functioning as a protecting layer at the time of pressing and a seed layer at the time of plating is coated on one surface of the primer, and this is called a primer-coated copper (PCC) as described above. In the case of the PCC, the primer resin layer is made of a resin composition such as epoxy or the like, and thus high modulus is not secured. Accordingly, when the PCC is used, it is general to laminate a prepreg (PPG) containing glass fabric.

The primer resin layer is made of at least one epoxy resin selected from a naphthalene based epoxy resin, a bisphenol A epoxy resin, a phenol novolac epoxy resin, a cresole novolac epoxy resin, a rubber modified epoxy resin, and a phosphorous-based epoxy resin, but is not limited thereto.

As such, when the PCC and PPG are laminated at the time of fabricating the multilayer printed circuit board by the SAP method, the adhesive strength therebetween is very important. Referring to FIG. 2, since the prior art depends on only adhesive strength using resin characteristics between the primer layer of the PCC and the resin composition of the PPG, the delamination may occur between the PCC and the PPG.

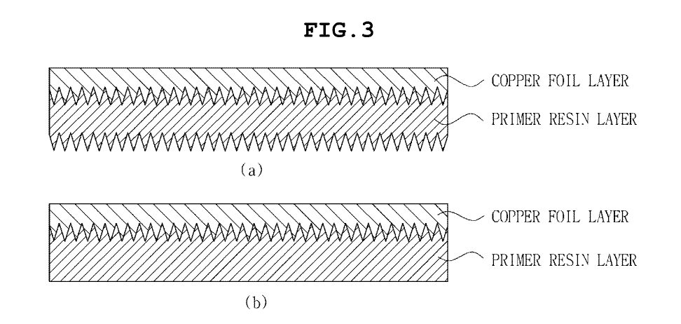

Therefore, referring to FIG. 3A, in the present invention, a PCC having a predetermined roughness formed on one surface of the primer resin layer thereof was formed. It was confirmed that the adhesive strength was further improved in a product where the PCC was laminated together with PPG than in a product of the prior art where a PCC has no roughness (FIG. 3B).

The thickness of the primer resin layer was larger than the thickness of the primer resin layer of the PCC by about 0.5 μm or larger, and here, the roughness generated when the roughness was transferred from the below-described template film was considered. In the present invention, the primer resin layer preferably has a thickness of 2 to 10 μm. If the thickness thereof is below 2 μm, the insulating function may be deteriorated, high modulus may not be obtained, and the ability to receive the roughness transferred is not sufficient. If above 10 μm, the thin film type multilayer printed circuit board is difficult to fabricate and there are problems in hole forming and plating at the time of via processing.

The PET film is preferably formed such that the surface thereof has an arithmetical average roughness in the range of 0.2 to 0.6 μm. If the average roughness is below 0.2, it is difficult to anticipate an increase effect in surface area and thus adhesive strength may be degraded. If above 0.6, it is difficult to fabricate a thin film substrate. Meanwhile, the maximum average roughness have a value of 2 to 6 μm, and this range is determined to avoid the same problems as described above.

Hereinafter, the primer-coated copper foil according to the present invention will be described in detail.

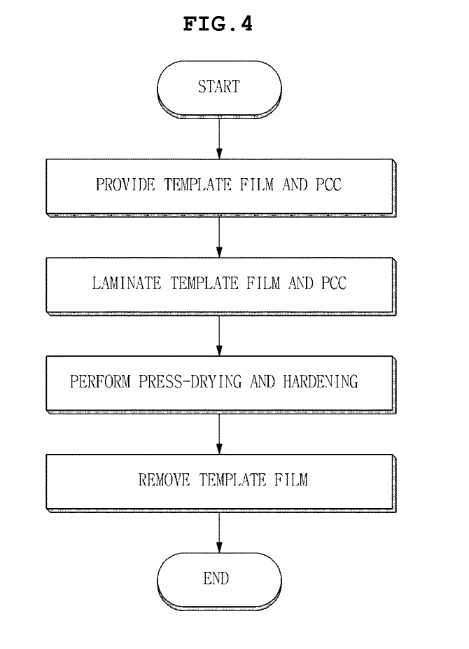

Referring to FIG. 4, in the present invention, the template film is used, and a polyethylene terephthalate (PET) film was used as a preferable template film, but the kind of the template film is not limited thereto. Meanwhile, the template film is formed by a PET film molding method such that the surface thereof has predetermined concave and convex shapes, and a release layer is formed on the surface having the concave and convex shapes.

The thickness of the release layer of the template film thus prepared is made to have very thin thickness, so that the concavo-convex structure on the surface of the PET film is also maintained through the surface of the release layer. The thickness of the release layer of the present invention is preferably 1 to 3 μm. If the thickness is below 1 μm, the release layer may not perform the function thereof in the step of removing the template film as described below. If above 3 μm, the roughness of the concavo-convex structure formed on the surface of the PET film may not be accurately transferred to the primer resin layer of the PCC.

The template film thus prepared was laminated on the primer-coated copper foil having no roughness. The fabricating processes were as follows. The primer resin layer, which is coated on the copper foil in order to form the primer-coated copper foil, is transformed into a B-stage by performing semi-drying at 120 to 140° C. for about 20 to 30 minutes, and then contacted with the primer of the prepared template film, which has a roughness transformed into a B-stage. After that, lamination was conducted for about 10 seconds under vacuum ambience (2 hPa or lower), temperature of about 110° C., and pressure of about 4 to 7 kgf/cm.

While the template film and the primer-coated copper foil were laminated as above, thermal hardening was further conducted for 40 to 60 minutes in the temperature range of 150 to 180□, so that complete hardening was conducted while the primer was laminated together with the template film having the roughness. In this step, a vacuum hardening machine or an atmospheric hardening machine may be used.

After completing the pressurizing, drying and hardening processes, the template film was removed. Since the release layer is formed on the template film, the template film is relatively easily removed, and thus components of the release layer hardly remains on the primer resin layer.

The primer-coated copper foil produced by the above procedure has an arithmetic average roughness value of 0.2 to 0.6 μm on the surface thereof.

Hereinafter, the present invention will be described in more detail with reference to the following examples, but the scope of the present invention is not limited thereto.

### EXAMPLE 1

A template film was formed on a polyethylene terephthalate (PET) film in a B-stage having a roughness formed on a surface thereof, by using a gravure coater, to have an arithmetic average roughness of 0.2 μm, and a releasing agent was coated thereon to have a thickness of 1 μm, to complete the template film. In addition, a 5 μm-thick primer resin layer was coated on a 2 μm-thick matte surface formed on a 18 μm-thick carrier copper foil by using a gravure coater. The thus prepared primer-coated copper foil and the template film were laminated, and the primer resin layer coated on the copper foil in order to form the primer-coated copper foil was semi-dried at about 130° C. for about 25 minutes, to be transformed into a B-stage, and then contacted with the primer of the prepared template film, which had a roughness transformed into a B-stage. After that, lamination was conducted for about 10 seconds under vacuum ambience (2 hPa), temperature of about 110° C., and pressure of about 6 kgf/cm. While the template film and the primer-coated copper foil were laminated as above, thermal hardening was conducted at a temperature of about 165° C. and for about an additional 50 minutes, so that complete hardening was conducted while the primer was laminated together with the template film having roughness. After that, the template film was removed, to fabricate a primer-coated copper foil having an arithmetic average thickness of 0.2 μm on a surface thereof. This primer-coated copper foil was laminated on the thus prepared prepreg, and then a vacuum press process was conducted to fabricate a multilayer printed circuit board.

### EXAMPLE 2

The template film was formed to have an arithmetic average roughness of 0.4 μm by using the same method as Example 1, and thus a primer-coated copper foil having roughness formed on the surface of the primer resin layer was formed, which was then laminated on the prepreg, to fabricate a multilayer printed circuit board.

As set forth above, the primer-coated copper foil according to the present invention has superior adhesive strength by having a uniform roughness on a surface therefore, which is bonded with the prepreg. Therefore, there can be provided a primer-coated copper foil having superior adhesive strength and a printed circuit board having the same.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A primer-coated copper foil, comprising:
a copper foil layer; and
a primer resin layer having a first surface on which the copper foil layer is coated and a second surface as a counter side on which a roughness is formed.

2. The primer-coated copper foil as set forth in claim 1, wherein the primer resin layer contains at least one epoxy resin selected from a naphthalene based epoxy resin, a bisphenol A epoxy resin, a phenol novolac epoxy resin, a cresole novolac epoxy resin, a rubber modified epoxy resin, and a phosphorous-based epoxy resin.

3. The primer-coated copper foil as set forth in claim 1, wherein the primer resin layer has a thickness of 2 to 10 μm.

4. The primer-coated copper foil as set forth in claim 1, wherein the roughness has an arithmetic average roughness value (Ra) of 0.2 to 0.6.

5. The primer-coated copper foil as set forth in claim 1, wherein the roughness has a maximum arithmetic average roughness value (Rz) of 2 to 6.

6. A method for producing a primer-coated copper foil having a roughness formed on a surface thereof, the method comprising:
providing a template film having one surface having a roughness formed thereon, on which a release layer is coated;
laminating a primer resin layer having a first surface on which a copper foil layer is coated and a second surface as an opposite side thereof on the template film such that the second surface of the primer resin layer is laminated on the release layer of the template film;
pressing the laminated template film and the primer-coated copper foil;
drying and hardening the pressed template film and primer-coated copper foil; and
removing the template film coated with the release layer.

7. The method as set forth in claim 6, wherein the release layer has a thickness of 1 to 3 μm.

8. The method as set forth in claim 6, wherein the template film is a polyethylene terephthalate film.

9. The method as set forth in claim 6, wherein the roughness has an arithmetic average roughness value (Ra) of 0.2 to 0.6.

10. The method as set forth in claim 6, wherein the roughness has a maximum arithmetic average roughness value (Rz) of 2 to 6.
